(19) United States
(12) Patent Application Publication
(10) Pub. No.: US 2012/0187991 A1
(43) Pub. Date: Jul. 26, 2012

(54) CLOCK STRETCHER FOR VOLTAGE DROOP MITIGATION

(75) Inventors: Visvesh SATHE, Fort Collins, CO (US); Samuel NAFFZIGER, Fort Collins, CO (US); Sanjay PANT, Fort Collins, CO (US)

(73) Assignee: Advanced Micro Devices, Inc., Sunnyvale, CA (US)

(21) Appl. No.: 13/013,013

(22) Filed: Jan. 25, 2011

(51) Int. Cl. H03L 7/06; H03K 3/00

(52) U.S. Cl. 327/158; 327/298

(57) ABSTRACT

A clock frequency of a clock signal used by a processor may be temporarily reduced to compensate for voltage droops in the power supply to the processor. A device may include a multiplexer to receive a group of phase shifted versions of the clock signal and to output one of the group of phase shifted versions of the clock signal as an output clock signal. A control component may receive the output clock signal from the multiplexer and a voltage droop event signal indicating whether a voltage droop event is occurring in a power supply. The control component may control, in response to the voltage droop event signal indicating the occurrence of the voltage droop event, the multiplexer to iteratively select the group of phase shifted versions of the clock signal to reduce the frequency of the output clock signal.

### BACKGROUND

Modern processors are designed and implemented to operate at a determined set of voltage supply-frequency points. Higher operating frequencies require the logic circuits in the processor to operate at a faster rate, which may be achieved by operating the processor at a higher supply voltage. Using a lower voltage supply than required may cause timing failures, which can be catastrophic to the operation of the processor.

Depending on the code being executed, the power requirements of a processor can vary drastically. For instance, as part of its operation, the software code may cause occasional spikes in processing activity, which may result in a sudden increase in power needed by the processor. These significant and sudden changes in drawn power, along with power distribution parasitics in the motherboard and the package, in which the processor is installed, can cause significant droops (and overshoots) in the supplied voltage, even through the power supply is providing the rated voltage needed for the processor to operate at the desired frequency.

To ensure error-free operation of the processor, it may be desirable to efficiently compensate for voltage droops.

### SUMMARY OF EMBODIMENTS OF THE INVENTION

In embodiments described herein, a clock stretcher circuit may compensate for voltage droops in a power supply by reducing the frequency of a clock supplied to a device that uses the power supply. In response to the detection of voltage droop, a control circuit may iteratively select a number of phases of the clock to generate an output clock signal that is a “stretched” (i.e., reduced frequency) version of the original clock signal.

According to one embodiment, a device may include a multiplexer to receive a number of phase shifted versions of a clock signal and to output one of the phase shifted versions of the clock signal as an output clock signal. The device may further include a control component to receive the output clock signal from the multiplexer and a voltage droop event signal indicating whether a voltage droop event is occurring in a power supply. The control component may control, in response to the voltage droop event signal indicating the occurrence of the voltage droop event, the multiplexer to iteratively select the phase shifted versions of the clock signal to reduce the frequency of the output clock signal and to statically select one of the phase shifted versions of the clock signal when the voltage droop event signal indicates that the voltage droop event is not occurring.

In another embodiment, a method comprises receiving, by a device, a number of phase shifted versions of an input clock signal, the input clock signal being used by a processor powered by a first power supply. The method may further include iteratively outputting, by the device, the phase shifted versions of the input clock signal to generate an output clock signal as a reduced frequency version of the input clock signal, the iteratively outputting being performed in response to a voltage droop occurring in the first power supply. The method may further include outputting, by the device, a statically selected one of the phase shifted versions of the input clock signal as the output clock signal, when the sequentially outputting, in response to the voltage droop, is not being performed.

In yet another embodiment, a system may include a delay locked loop (DLL) to receive a first clock signal and output delayed versions of the first clock signal as a number of phase shifted versions of the first clock signal; a multiplexer to receive the number of phase shifted versions of the first clock signal and to output one of the plurality of phase shifted versions of the first clock signal as an output clock signal, where the output clock signal is used by a processor that is powered from a first power supply; a droop detector to generate a voltage droop event signal when a voltage droop occurs in the first power supply, the droop detector generating the voltage droop event signal based on a comparison of a phase of one of the delayed versions of the first clock signal, as output from the DLL, and a phase of a second delayed version of the first clock signal; and a control component to receive the output clock signal from the multiplexer and the voltage droop event signal, the control component controlling, in response to the voltage droop event signal indicating the occurrence of the voltage droop, the multiplexer to iteratively select the phase shifted versions of the clock signal to reduce a frequency of the output clock signal and to statically select one of the phase shifted versions of the clock signal when the voltage droop event signal indicates that the voltage droop event is not occurring.

### BRIEF DESCRIPTION OF THE DRAWINGS

The accompanying drawings, which are incorporated in and constitute a part of this specification, illustrate one or more embodiments described herein and, together with the description, explain these embodiments. In the drawings:

FIGS. 1A and 1B are diagrams illustrating an example system in which concepts described herein may be implemented.

FIG. 2 is a diagram illustrating an example of voltage droop in response to a sudden increase in activity of a processor;

FIG. 3 is a diagram illustrating an example of a clock stretcher circuit;

FIG. 4 is a flow chart illustrating an example process for performing clock stretching;

FIG. 5 is a diagram illustrating example waveforms that illustrate the operation of a clock stretcher circuit;

FIG. 6 is a diagram illustrating an example of a system that may be used with a clock stretcher circuit;

FIG. 7 is a diagram illustrating additional example details of portions of a system; and

FIG. 8 is a diagram illustrating example waveforms that illustrate the operation of a clock stretcher circuit in conjunction with a system for providing a droop event signal.

### DETAILED DESCRIPTION

The following detailed description refers to the accompanying drawings. The same reference numbers in different drawings may identify the same or similar elements. Also, the following detailed description does not limit the invention.

### Overview

Systems and/or methods described herein include circuitry to compensate for voltage “droops,” experienced by a processor, by reducing the clock frequency to the processor. The circuitry may include a clock stretcher circuit in which a number of different phase versions of a clock signal are input to a multiplexer. In response to the detection of voltage droop, a control circuit may sequentially select a number of the phases to generate an output core clock signal that is a “stretched” (i.e., reduced frequency) version of the original clock signal. When the voltage droop is no longer detected, the multiplexer may statically select a single one of the different phase versions of the clock signal to output as the core clock signal. Through the operation of the clock stretcher circuit, when a voltage droop is detected, the core clock frequency may be reduced, which can reduce timing failures of the processor due to the transient drop in supply voltage (i.e. the voltage droop).

Additionally, in some implementations, the different clock phases used by the clock stretcher circuit may be generated from a main clock signal using a delay-locked-loop (DLL). The DLL may be powered from the same power source as the processor. The effect of a voltage droop on the operation of the DLL may be used to trigger the clock stretcher circuit.

### Example System

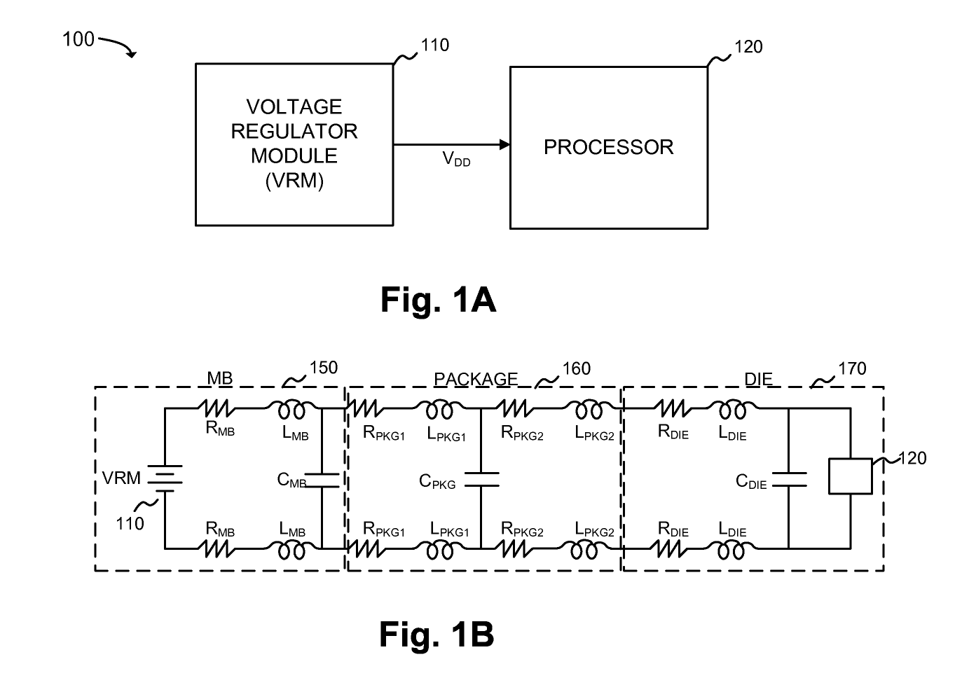

FIGS. 1A and 1B are diagrams illustrating an example system 100 in which concepts described herein may be implemented.

System 100, as shown in FIG. 1A, may include a voltage regulator module (VRM) 110 and a processor 120. VRM 110 may supply regulated power to processor 120. VRM 110 may, for example, supply a regulated input voltage, V_{DD}, to processor 120. In some implementations, VRM 110 may be controllable to supply power to processor 120 at a number of different voltage levels. For example, processor 120 may be designed to operate at a number of different frequencies, each of which may require a different input voltage. Processor 120 may control VRM 110 to supply the voltage level that is required for current operation of the processor.

Processor 120 may generally represent a processing circuit, such as a central processing unit (CPU), graphical processing unit (GPU), or other processing device. Processor 120 may be a synchronous processor that operates based on one or more clock signals. Processor 120 may be configured to operate within a range of potential clock frequencies. In general, higher clock frequencies may cause the logic circuits in processor 120 to operate at a faster rate, and this increase in speed can be achieved by operating processor 120 at a higher supply voltage. Using a lower voltage supply than required, however, can potentially cause timing failures, which may be catastrophic to the operation of processor 120.

The processing throughput/power load at any particular time, of processor 120, may be influenced by the software code currently being executed by processor 120. For instance, the software code may cause occasional spikes in processing activity, which may result in a sudden increase in power needed by processor 120.

FIG. 1B is a diagram illustrating a simplified model of a power distribution network from VRM 110 to processor 120. The power distribution network shown in FIG. 1B may be, for example, a power distribution network for an implementation in which processor 120 includes a CPU in a personal computer. The power distribution network may include a motherboard (MB) 150, a package portion 160, and a processor die 170. VRM 110 may be included in motherboard 150. Motherboard 150, package 160, and die 170 can include a number of parasitics, shown as a number of resistive, inductive, and capacitive values between VRM 110 and processor 120. These parasitics, in conjunction with sudden changes in current drawn from VRM 110, can result in significant droops and overshoots in the voltage provided to processor 120, even though VRM 110 may be providing the rated voltage needed for processor 120 to operate at the desired frequency.

In FIG. 1B, motherboard 150 may be modeled as including resistances R_{MB}, inductances L_{MB}, and capacitance C_{MB}. Package 160 may be modeled as including resistances R_{pkg1} and R_{pkg2}, inductances L_{pkg1} and L_{pkg2}, and capacitance C_{pkg}. Die 170 may be modeled as including resistances R_{die}, inductances L_{die}, and capacitance C_{die}.

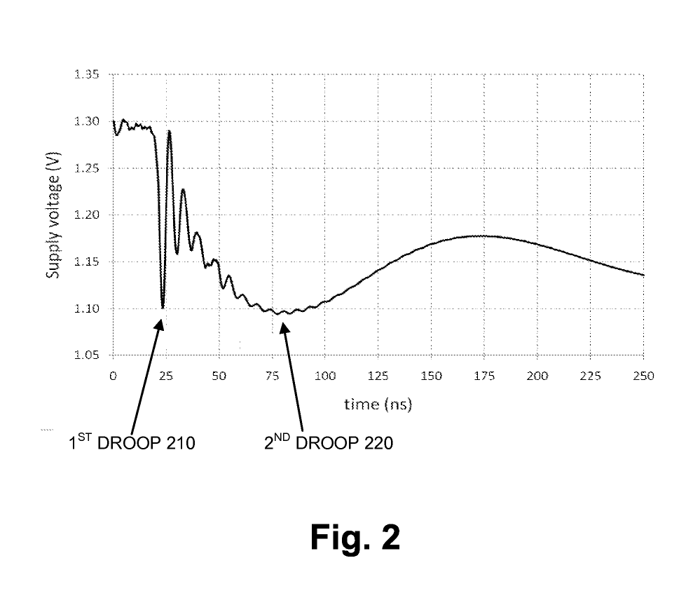

FIG. 2 is a diagram illustrating an example of voltage droop in response to a sudden increase in activity of processor 120. As shown in FIG. 2, assume that VRM 110 is supplying a 1.3 volt power signal. Assume that at time zero, a sudden spike in activity of processor 120 occurs. The supply voltage delivered to processor 120, in response to the spike in activity, may vary as shown in FIG. 2. In particular, a first droop 210 may occur, followed by a second droop 220.

### Clock Stretching

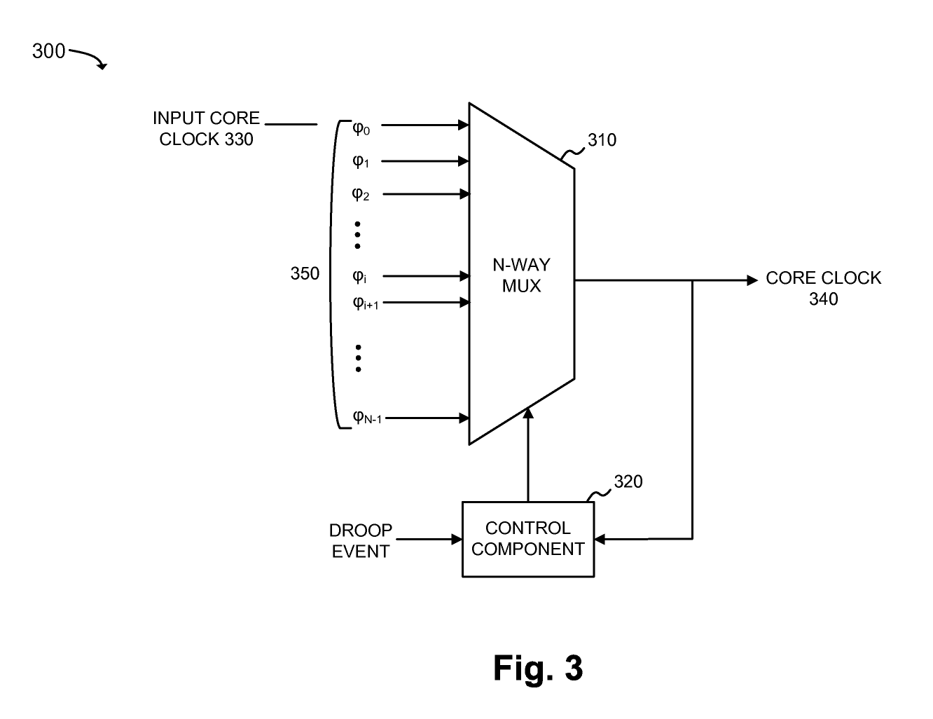

FIG. 3 is a diagram illustrating an example of a clock stretcher circuit 300. Clock stretcher circuit 300 may be a device implemented within, for example, processor 120 or external to processor 120. In general, clock stretcher circuit 300 may operate to, in response to a droop event, “stretch” a clock signal, destined for processor 120, to lower its frequency and, thus, decrease the current drawn by processor 120. By reducing the current drawn by processor 120, a failure of processor 120 may potentially be avoided. Input core clock 330 is illustrated in FIG. 3 as the input clock signal that is to be provided to processor 120, as core clock 340, after operation of clock stretcher circuit 300.

As shown in FIG. 3, clock stretcher circuit 300 may include multiplexer (MUX) 310 and control component 320. Multiplexer 310 may receive a number of phase shifted versions of input core clock 330, labeled as phase shifted clock signals 350. As shown, N phase shifted versions of input core clock 330 are illustrated, labeled as φ₀ through φ_{N-1}. Each phase shifted clock should be of substantially equal frequency. In one implementation, the phase of each of the phase shifted clock signals 350 may be approximately equally offset from one another, so, for example, φ₁ may be offset by 2π/N from φᵢ₋₁ and φᵢ₊₁.

Control component 320 may receive core clock 340, as output by multiplexer 310. Control component 320 may, in response to an indication of an occurrence of a droop in the supply voltage, V_{DD}, control multiplexer 310 to perform clock stretching of input core clock 330. In one implementation, control component 320 may be implemented using a finite state machine (FSM).

Clock stretching, as will be described in more detail below, may be performed by sequentially selecting different ones of the phase shifted clock signals 350 for output from multiplexer 310 to effectively synthesize a new stretched version of input core clock 330, which is output as core clock 340. During normal operation, however, when the supply voltage is at its nominal value, control component 320 may hold the selection of multiplexer 310 at a single value, thus passing a single one of phase shifted clock signals 350 as core clock 340 (i.e., clock stretching is not performed).

Although FIG. 3 shows example components of clock stretcher circuit 300, in other embodiments, clock stretcher circuit 300 may include fewer components, different components, differently arranged components, or additional components than depicted in FIG. 3. Alternatively, or additionally, one or more components of clock stretcher circuit 300 may perform one or more other tasks described as being performed by one or more other components of clock stretcher circuit 300.

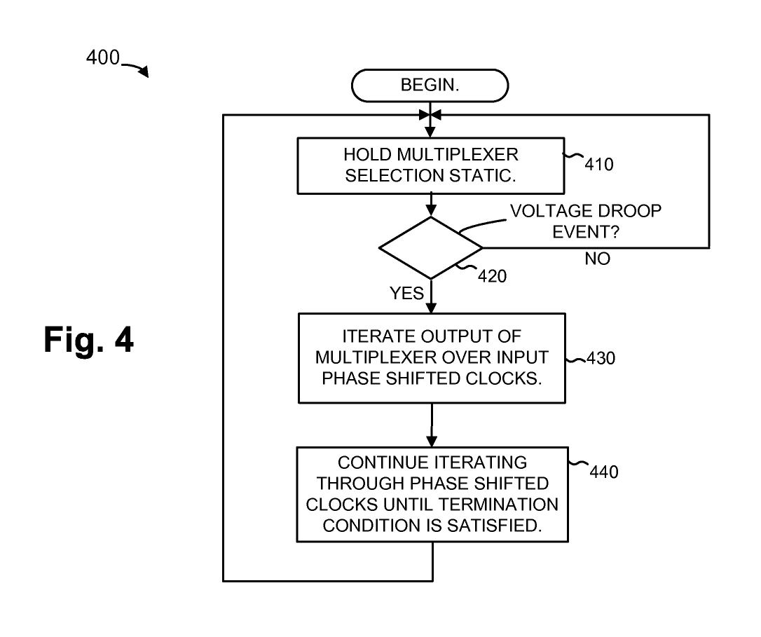

FIG. 4 is a flow chart illustrating an example process 400 for performing clock stretching by clock stretcher circuit 300. Process 400 may be performed by control component 320 to control multiplexer 310.

Process 400 may include holding the selection of multiplexer 310 at a static value (block 410). In other words, one of phase shifted clock signals 350 may be passed through multiplexer 310 as core clock 340. Because the frequencies of each of phase shifted clock signals 350 are equal, the particular phase shifted clock to select by multiplexer 310 may be arbitrary. At this point, the frequency of core clock 340 will be equal to the frequency of any of phase shifted clock signals 350.

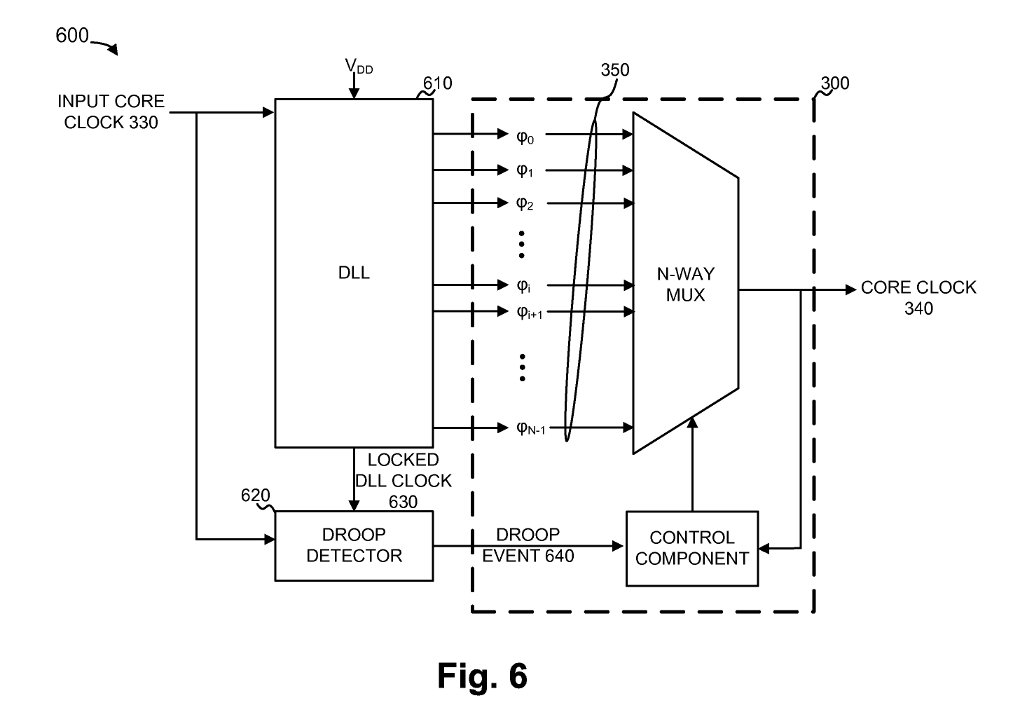

Process 400 may further include receiving an indication of a voltage droop event (block 420). Detection of the droop event will be described in more detail below with reference to FIGS. 6-8.

In response to the voltage droop event, (block 420—YES), control component 320 may control multiplexer 310 to iterate through phase shifted clock signals 350 (block 430). Control component 320 may perform the iteration based on core clock 340. For instance, at each clock cycle of core clock 340, control component 320 may select the next one of phase shifted clock signals 350. For example, in a first iteration clock φ₀ may be selected, clock φ₁ may be selected in the next iteration, and clock φ₂ in the next iteration, and so forth. Phase shifted clock signals 350 may be selected in a ring configuration, so after selecting clock φ_{N-1}, control component 320 may select clock φ₀. More generally, instead of selecting the next phase shifted clock signals 350 at each iteration, control component 320 may increment through the ring of phase shifted clock signals 350 using an increment integer value M. For example, for M equal to two, control component 320 may select the iteration sequence clock φ₀, φ₂, φ₄, etc. For M equal to one, as described above, control component 320 may select the iteration sequence clock φ₀, φ₁, φ₂, etc. In another possible alternative, the next phase shifted clock signals 350 at each iteration may be selected based on a non-constant value of M. For example, a clock selection sequence, in which clock φ₀ through clock φ₉ are available, may include clock φ₀, clock φ₁, clock φ₂, clock φ₄, clock φ₇, clock φ₈, clock φ₉, clock φ₀ etc.

Process 400 may further include continuing to iterate through phase shifted clock signals 350 until a termination condition is satisfied (block 440). In one example, the termination condition may be a predetermined number of cycles of core clock 340 or a predetermined time interval. Additionally or alternatively, the termination condition may include the cessation of the droop event signal, such as may occur when V_{DD} returns to its long term average. Other events may cause the termination condition to be satisfied. In response to the termination condition, control component 320 may return to holding the selection of multiplexer 310 at a static value (block 410).

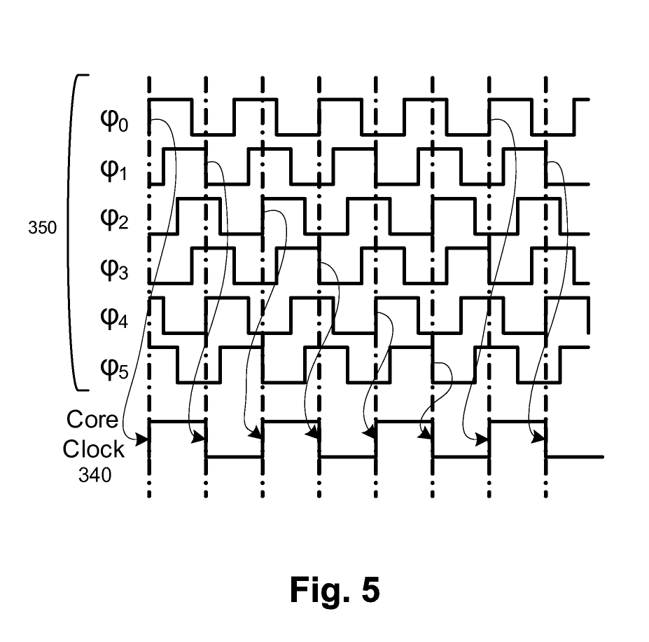

FIG. 5 is a diagram illustrating example waveforms that illustrate the operation of clock stretcher circuit 300. As shown, assume that phase shifted clock signals 350 include six clock signals, labeled as φ₀ through φ₅. Core clock 340 is the output clock synthesized by the operation of clock stretcher circuit 300. At each edge of core clock 340, control component 320 may control multiplexer 310 to select the next one of phase shifted clock signals 350, as illustrated by the curved lines in FIG. 5. The resulting core clock 340 may be a stretched version of phase shifted clock signals 350, in which, by selecting successive phases that are 2π/N apart, the frequency of core clock 340 is reduced to N/(N+2)*f where N is the number of phase shifted clock signals 350 (six in this example) and f is the frequency of each of phase shifted clock signals 350.

The transient frequency reduction of core clock 340 may be designed so that it is sufficient to ensure that timing errors of processor 120, due to the voltage droop, are avoided. Furthermore, the reduced frequency may reduce the load current (which is proportional to the operating frequency), thereby further reducing the magnitude of the voltage droop itself. Once the termination condition is reached for the clock stretching (e.g., the supply voltage returns to the nominal voltage), control component 320 may stop selecting successive clock phases and the selected one of phase shifted clocks 350 may remain selected as core clock 340, returning the core clock frequency to f. If larger frequency reductions are desired, control component 320 may be implemented to “march” clock phases by 2 m cycles every output clock edge, resulting in an output frequency of N/(N+2 m)*f

Additionally, as described above, when a voltage droop is not occurring, clock stretcher circuit 300 may hold multiplexer 310 in a static selection, advantageously avoiding any additional jitter that may be introduced into core clock 340 during clock stretching. The added jitter during clock stretching may be acceptable because the frequency is lower.

The techniques described above for handling voltage droops may lead to a number of advantages. As a fully digital implementation, clock stretcher circuit 300 may not require significant rework of an existing design when migrating to a new process generation. Additionally, clock stretcher circuit 300, unlike droop mitigation techniques based on architectural throttling, is a stand alone design which may not require existing processor modules to be re-designed. Additionally, clock stretcher circuit 300 may be capable of handling second-droop events that occur relatively shortly after the first droop event. Still further, during normal (non-droop operation), clock stretcher circuit 300 may not introduce jitter into the clock signal. Further, by using a sufficient number of effective clock phases (through multiple clock phases as inputs or through interpolation of provided phases), clock stretcher circuit 300 may be capable of achieving fine grained frequency reduction in response to the magnitude of the droop.

### Droop Detection

FIG. 6 is a diagram illustrating an example of a system 600 that may be used with clock stretcher circuit 300. System 600 may detect the droop events and generate phase shifted clock signals 350 that are input to clock stretcher circuit 300.

System 600 may include a delay locked loop (DLL) 610 and a droop detector component 620. DLL 610 may receive input core clock 330, such as a clock signal generated using a phase locked loop (PLL), and output the phase shifted (i.e., delayed) clock signals 350 to clock stretcher circuit 300. DLL 610 may also output an additional delayed version of input core clock 330, labeled as locked DLL clock 630, to droop detector component 620.

DLL 610 may generally operate to provide phase shifted clock signals 350 that are locked into their respective phase shifts with respect to input core clock 330. DLL 610 may include a number of delay elements and may operate to compare the phase of one of its outputs to input core clock 330 to generate an error signal which is then integrated and fed back as the control to the delay elements. The integration may allow the phase lock error to go to zero.

DLL 610 may be powered by V_{DD} from VRM 110. Because DLL 610 is powered by the same power supply as processor 120, a voltage droop in the supplied power will affect DLL 610. The effect of the voltage droop may include a “slowing down” of DLL 610, which may result in additional delay in locked DLL clock 630.

Droop detector component 620 may received locked DLL clock 630 and input core clock 330. The change in delay in locked DLL clock 630, due to a droop event, may be detected by droop detector component 620 and used to generate droop event signal 640.

Although FIG. 6 shows example components of system 600, in other embodiments, clock stretcher system 600 may include fewer components, different components, differently arranged components, or additional components than depicted in system 600. Alternatively, or additionally, one or more components of system 600 may perform one or more other tasks described as being performed by one or more other components of system 600.

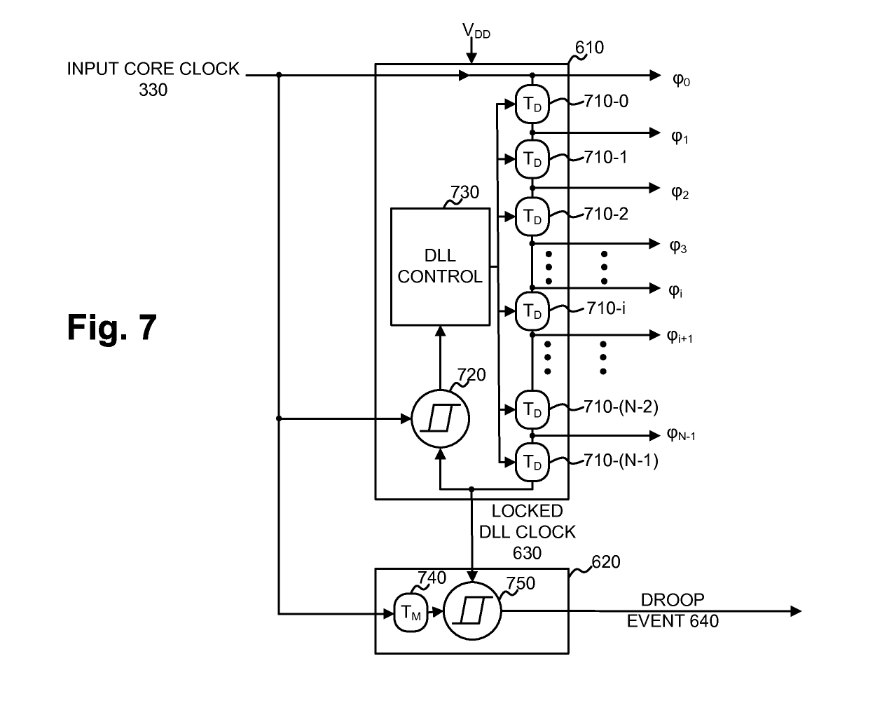

FIG. 7 is a diagram illustrating additional example details of portions of system 600.

As shown in FIG. 7, DLL 610 may include a number of series connected programmable delay elements 710-0 through 710-(N−1), a phase detector 720, and DLL control component 730. Programmable delay elements 710-0 through 710-(N−1) may each include a delay circuit, such as a combination of an inverter and a variable capacitor, in which the delay can be changeable by DLL control component 730. Each delay element 710 may introduce a delay (phase shift) into its input clock signal.

Phase detector 720 may include logic to receive input core clock 330 and locked DLL clock 630, and, in response, detect a phase difference between its inputs. Phase detector 720 may output a signal indicative of the phase difference. Phase detector 720 may, for example, output a voltage signal proportional to the phase difference. The output of phase detector 720 may be received by DLL control component 730.

DLL control component 730 may include logic to control delay elements 710, based on the output of phase detector 720, to lock the phases of phase shifted clock signals 350 relative to input core clock 330. In one implementation, DLL control component 730 may include a finite state machine.

As is further shown in FIG. 7, droop detector component 620 may include a delay element 740 and a phase detector 750. Delay element 740 may introduce a delay into input core clock 330. Delay element 740 may include a combination of an inverter and a variable capacitor, or other delay logic. In one implementation, the delay may be a programmable delay. The programmable delay may be set such that it can be used to detect when locked DLL clock 630 changes a threshold amount of phase due to a voltage droop. As mentioned previously, the reduction in V_{DD} due to a voltage droop may affect DLL 610, causing locked DLL clock 630 to shift in phase relative to input core clock 330. The delay introduced by delay element 740 may be selected so that phase detector 750 will be triggered by the change in phase of locked DLL clock 630, to thus generate droop event signal 640. Stated differently, when an initial voltage droop is detected by droop detector component 620 and the delay in delay elements 710 matches the stretched clock period, DLL 610 may enter a “low bandwidth” mode, which prevents DLL 610 from correcting delay elements 710 in response to first and second droop events. Consequently, the droop event may cause the delay through delay elements 710 to increase. The increased delay may be compared with the delayed PLL clock (input core clock 330, after delay by delay element 740) to identify the instant when locked DLL clock 630 exceeds the delayed input core clock. The amount of delay of delay element 740 may be set to the voltage droop threshold.

Additionally, since DLL 610 is supplied by the main core voltage (V_{DD}), and the bandwidth of DLL 610 may be deliberately set to be below the first and second droop frequencies, the voltage droop may cause the delay cell delays to push out. As such, the rising clock edge of φ_{N-2} may approach φ₀, with the result that selecting a rising edge from φ₀ immediately after a rising edge from φ_{N-2} (with φ_{N-1} being selected as the falling edge between these two edges) may result in a reduction of the stretch amount, and cause a potential timing failure in processor 120 due to an inadequate increase in the clock period. To avoid this hazard, the phase selection of DLL control component 730 may select φ₀ immediately after φ_{N-4} (with φ_{N-3} being selected as the falling edge between these two edges). The number of phases chosen for the clock stretch may be determined by the expected droop in the supply voltage, such that a steady supply voltage applied to delay element 710 causes φ_{N-2} to line up with φ₀. Such a phase selection methodology may ensure a nearly uniform clock stretch, as different phases are presented as core clock 340. In implementations in which different operating voltages may be used, the expected droop in the supply voltage may vary based on the operating voltage. In this situation, instead of choosing the number of phases for the clock stretch based on the expected droop, DLL control component 730 may be configurable so that the last phase chosen depends on the current operating voltage. Further, in an implementation where a regulated supply other than VDD is available, DLL 610 can operate at a voltage-droop invariant supply. This can prevent the variation in delay of the delay elements constituting DLL 610. Therefore, in such an implementation, there is no need for DLL control component 730 to skip the selection of the last phase φ_{N-1} while stretching the clock.

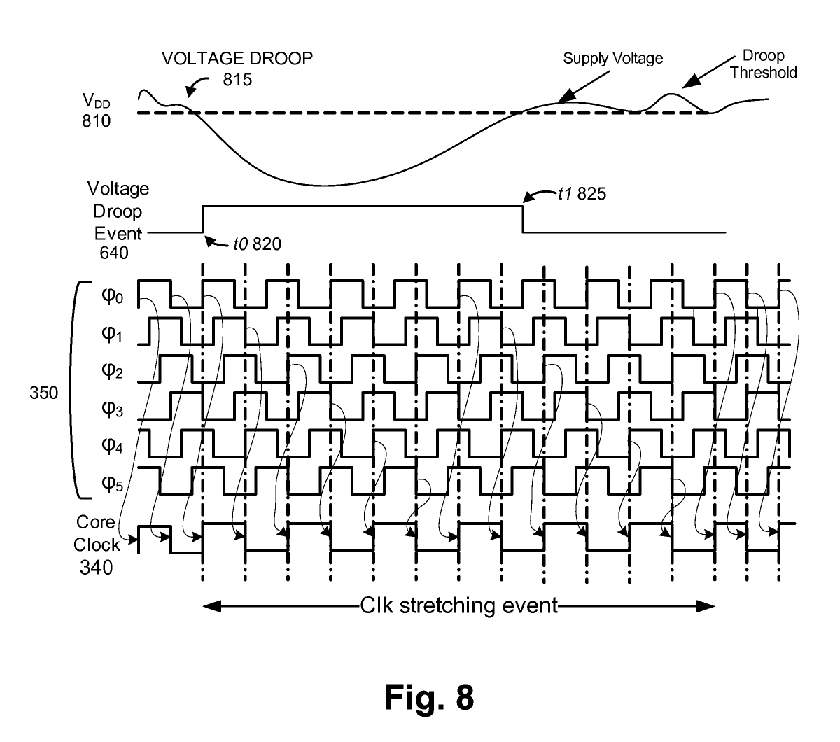

FIG. 8 is a diagram illustrating example waveforms that illustrate the operation of clock stretcher circuit 300 in conjunction with system 600 for providing droop event signal 640. As shown, assume that phase shifted clock signals 350 include six clock signals, labeled as φ₀ through φ₅. Core clock 340 is the output clock synthesized by the operation of clock stretcher circuit 300. Voltage droop event signal 640 may be the signal output from droop detector component 620 and may control whether clock stretching is to be performed. V_{DD} 810 may represent the supply voltage from VRM 110, and may be used to supply processor 120 and DLL 610.

In FIG. 8, a logic high for voltage droop event signal 640 may signal that clock stretching is to be performed. A logic low value for voltage droop event signal 640 may correspondingly cause clock stretcher circuit 300 to stop operation and hold the selection of multiplexer 310 static at one of the input phase shifted clock signals 350.

As shown in FIG. 8, in response to a voltage droop 815 in V_{DD} 810, the voltage droop may be detected by droop detector component 620 and voltage droop event signal 640 may be activated (e.g., made logic high) at time t0 820.

At each edge of core clock 340, when voltage droop event signal 640 is logic high, control component 320 may control multiplexer 310 to select the next one of phase shifted clock signals 350, as illustrated by the curved lines in FIG. 8. The resulting core clock 340 may be a stretched version of phase shifted clock signals 350, in which, by selecting successive phases that are 2π/N apart, the frequency of core clock 340 is reduced by N/(N+2)*f, where N is the number of phase shifted clock signals 350 (six in this example) and f is the frequency of each of phase shifted clock signals 350.

The transient frequency reduction of core clock 340 may be designed so that it is sufficient to ensure that timing errors of processor 220, due to the voltage droop, are avoided. Once voltage droop event signal 640, output by droop detector 620, returns to a logic low value, at time t1 825, control component 320 may stop selecting successive clock phases and the selected phase shifted clock may remain selected as core clock 340, returning the core clock frequency to f. If larger frequency reductions are desired control component 220 may be implemented to “march” clock phases by 2 m cycles every output clock edge, resulting in an output frequency of N/(N+2 m)*f.

With DLL 610 and droop detector component 620, as shown in FIGS. 6-8, DLL 610 may advantageously serve the dual purpose of generating phase shifted clock signals 350 and may provide a delay line for the purpose of droop detection.

In one implementation, at the termination event (e.g., voltage droop event signal 640 transitioning to logic low), control component 320 may continue to iterate through phase shifted clock signals 350 until φ₀ is once again selected. Such a methodology may enable clock stretcher circuit 300 to avoid additional jitter that may be introduced due to the increased latency between input core clock 350 and core clock 340 through the delay elements 710.

Additionally, with DLL 610 and droop detector component 620, the voltage droops detected by droop detector component 620 may be droops that are detected based on a short term excursion of V_{DD} (i.e., the voltage droop) relative to the long term average value of V_{DD}. This can be advantageous with processors that are able to accept different nominal supply voltages as DLL 610 and droop detector component 620 may automatically adapt to the new long term average supply voltage level without requiring configuration relating to measurement of absolute voltage levels.

The foregoing description of embodiments provides illustration and description, but is not intended to be exhaustive or to limit the invention to the precise form disclosed. Modifications and variations are possible in light of the above teachings or may be acquired from practice of the invention.

For example, while a series of blocks has been described with regard to FIG. 4, the order of the blocks may be modified in other embodiments. Further, non-dependent blocks may be performed in parallel.

It will be apparent that aspects, as described above, may be implemented in many different forms of software, firmware, and hardware in the embodiments illustrated in the figures. The actual software code or specialized control hardware used to implement these aspects should not be construed as limiting. Thus, the operation and behavior of the aspects were described without reference to the specific software code—it being understood that software and control hardware could be designed to implement the aspects based on the description herein.

Even though particular combinations of features are recited in the claims and/or disclosed in the specification, these combinations are not intended to limit the invention. In fact, many of these features may be combined in ways not specifically recited in the claims and/or disclosed in the specification.

No element, block, or instruction used in the present application should be construed as critical or essential to the invention unless explicitly described as such. Also, as used herein, the article “a” is intended to include one or more items. Where only one item is intended, the term “one” or similar language is used. Further, the phrase “based on” is intended to mean “based, at least in part, on” unless explicitly stated otherwise.

What is claimed is:

1. A device comprising:
a multiplexer to receive a plurality of phase shifted versions of a clock signal and to output one of the plurality of phase shifted versions of the clock signal as an output clock signal; and
a control component to control, in response to a voltage droop event signal indicating an occurrence of a voltage droop event in a power supply, the multiplexer to iteratively select the plurality of phase shifted versions of the clock signal to reduce a frequency of the output clock signal and to statically select one of the phase shifted versions of the clock signal, as the output clock signal, when the voltage droop event signal indicates that the voltage droop event is not occurring.

2. The device of claim 1, where the plurality of phase shifted versions of the clock signal are equally spaced in phase from one another.

3. The device of claim 1, where the frequency of the output clock signal is reduced by N/(N+2), where N is a quantity of the plurality of phase shifted versions of the clock signal.

4. The device of claim 1, where the control component controls the multiplexer to:
iteratively select the plurality of phase shifted versions of the clock signal for a predetermined time period or a predetermined number of cycles of the output clock signal.

5. The device of claim 1, where the control component controls the multiplexer to:
iteratively select the plurality of phase shifted versions of the clock signal until cessation of assertion of the voltage droop event signal.

6. The device of claim 1, where the one of the phase shifted versions of the clock signal that is statically selected when the voltage droop event signal indicates the voltage droop event is not occurring includes a first phase shifted one of the plurality of phase shifted versions of the clock signal.

7. The device of claim 1, further comprising:
a delay locked loop (DLL) to receive the clock signal and to output delayed versions of the first clock signal, the output delayed versions of the first clock signal including the plurality of phase shifted versions of the clock signal and a locked DLL clock signal; and
a droop detector component to receive the locked DLL clock signal and to generate the voltage droop event signal based on a comparison of a phase of the locked DLL clock signal and a phase of a delayed version of the first clock signal.

8. The device of claim 7, where the DLL is powered by the power supply in which the voltage droop event is detected.

9. The device of claim 7, where the droop detector component further includes:
a delay element to delay the clock signal; and
a phase detector to detect a phase difference in an output of the delay element and the locked DLL clock signal, and, based on the phase difference, generate the voltage droop event signal.

10. The device of claim 7, where the DLL includes:
a plurality of serially connected delay elements to receive the clock signal;
a phase detector to generate a phase difference signal based on the first clock signal and on an output of the serially connected delay elements; and
a DLL control component to control the plurality of serially connected delay elements based on the generated phase difference signal.

11. The device of claim 10, where the control component includes a finite state machine.

12. A method comprising:
receiving, by a device, a plurality of phase shifted versions of an input clock signal, the input clock signal being used by a processor powered by a power supply;
iteratively outputting, by the device, the plurality of phase shifted versions of the input clock signal to generate an output clock signal as a reduced frequency representation of the input clock signal, the iteratively outputting being performed in response to a voltage droop occurring in the power supply; and
outputting, by the device, a statically selected one of the plurality of phase shifted versions of the input clock signal as the output clock signal, when the sequentially outputting, in response to the voltage droop, is not being performed.

13. The method of claim 12, further comprising:
generating the plurality of phase shifted versions of the input clock signal so that adjacent ones of the plurality of phase shifted versions of the input clock signal are equally spaced, in phase, from one another.

14. The method of claim 12, where a frequency of the output clock signal is reduced by N/(N+2) relative to the input clock signal, where N is a quantity of the plurality of phase shifted versions of the input clock signal.

15. The method of claim 12, where iteratively outputting the plurality of phase shifted versions of the clock signal is performed for a predetermined time period or a predetermined number of cycles of the output clock signal.

16. The method of claim 12, where iteratively selecting the plurality of phase shifted versions of the input clock signal in response to the voltage droop is performed until cessation of a signal indicating an occurrence of the voltage droop.

17. The method of claim 12, further comprising:
generating the plurality of phase shifted versions of the input clock signal using a delay locked loop (DLL); and
generating a voltage droop event signal, to indicate the occurrence of the voltage droop, based on a comparison of a phase of an output of the DLL and a phase of a delayed version of the input clock signal.

18. The method of claim 17, where the DLL is powered by the power supply.

19. A system comprising:
a delay locked loop (DLL) to receive a clock signal and output delayed versions of the clock signal as a plurality of phase shifted versions of the clock signal;
a multiplexer to receive the plurality of phase shifted versions of the clock signal and to output one of the plurality of phase shifted versions of the clock signal as an output clock signal, where the output clock signal is used by a processor that is powered from a power supply;
a droop detector to generate a voltage droop event signal when a voltage droop occurs in the power supply, the droop detector generating the voltage droop event signal based on a comparison of a phase of one of the delayed versions of the clock signal, as output from the DLL, and a phase of a second delayed version of the clock signal; and
a control component to receive the voltage droop event signal, the control component controlling, in response to the voltage droop event signal, the multiplexer to iteratively select the plurality of phase shifted versions of the clock signal to reduce a frequency of the output clock signal and to statically select one of the phase shifted versions of the first clock signal when the voltage droop event is not occurring.
